(19) United States
(12) Patent Application Publication
(10) Pub. No.: US 2026/0165106 A1
(43) Pub. Date: Jun. 11, 2026

(54) FORMING ZERO-TRACK SKIP SUPER VIA

(71) Applicant: International Business Machines Corporation, Armonk, NY (US)

(72) Inventors: Kamal Rudra, Albany, NY (US); Ruilong Xie, Niskayuna, NY (US); Kishore Natarajan, Albany, NY (US); Chih-Chao Yang, Glenmont, NY (US); Yann Mignot, Slingerlands, NY (US)

(21) Appl. No.: 18/973,499

(22) Filed: Dec. 9, 2024

(51) Int. Cl. H01L 23/522; H01L 21/768; H01L 23/532

(52) U.S. Cl. CPC H10W 20/42; H10W 20/057; H10W 20/069; H10W 20/074; H10W 20/4403

(57) ABSTRACT

Embodiments of the invention disclose structures and a method of making the structures. According to an embodiment, the structure includes an Mx−1 metal level, an Mx metal level above the Mx−1 metal level, and an Mx+1 metal level above the Mx metal level. The structure further includes a cut region in the Mx metal level, where the cut region has an outer layer spacer, and a super via connecting the Mx+1 metal level to the Mx−1 metal level through a center of the outer layer spacer.

### BACKGROUND

The present invention generally relates to semiconductor structures, and more particularly relates to forming a zero-track skip super via.

Forming a super via (SVIA) without track skips is advantageous for increasing circuit density but runs the risk of creating a short between the SVIA and a nearby metal line. While a smaller SVIA may be less likely to short with the nearby metal line, the smaller SVIA may result in a connection with an Mx−1 having a high resistance path and minimal contact area.

### SUMMARY

According to an embodiment of the present invention, a structure is provided. The structure includes an Mx−1 metal level, an Mx metal level above the Mx−1 metal level, and an Mx+1 metal level above the Mx metal level. The structure further includes a cut region in the Mx metal level, where the cut region has an outer layer spacer, and a super via connecting the Mx+1 metal level to the Mx−1 metal level through a center of the outer layer spacer.

According to another embodiment of the present invention, a structure is provided. The structure includes a super via connecting an Mx−1 metal level to an Mx+1 metal level, wherein the super via is insulated from an intermediate Mx metal level by an outer layer spacer.

According to another embodiment of the present invention, a method is provided. The method includes forming an Mx−1 metal level within a first interlayer dielectric (ILD), forming an etch stop layer (ESL) on top of the Mx−1 metal level and the first ILD, and forming a second ILD on top of the ESL. The method further includes forming an Mx cut in the second ILD, filling the Mx cut with a dielectric layer spacer and a dielectric core, and forming an Mx patterning in the second ILD selective to the Mx cut. The method additionally includes filling the Mx patterning to form an Mx metal level, recessing the Mx metal level, and filling the recesses with a dielectric cap. Furthermore, the method includes forming a third interlayer dielectric and forming Mx+1 trenches within the third interlayer dielectric. Lastly, the method includes forming a self-aligned skip via that etches the dielectric core, selective to the dielectric layer spacer, and forming a full-aligned via by selectively removing the dielectric cap.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIG. 2 and FIG. 3 are cross-sectional views of a semiconductor structure 100, according to an embodiment of the invention;

FIG. 4 and FIG. 5 are cross-sectional views of the semiconductor structure 100, according to an embodiment of the invention;

FIG. 6 and FIG. 7 are cross-sectional views of the semiconductor structure 100, according to an embodiment of the invention;

FIG. 8 and FIG. 9 are cross-sectional views of the semiconductor structure 100, according to an embodiment of the invention;

FIG. 10 and FIG. 11 are cross-sectional views of the semiconductor structure 100, according to an embodiment of the invention;

FIG. 12 and FIG. 13 are cross-sectional views of the semiconductor structure 100, according to an embodiment of the invention;

FIG. 14 and FIG. 15 are cross-sectional views of the semiconductor structure 100, according to an embodiment of the invention;

FIG. 16 and FIG. 17 are cross-sectional views of the semiconductor structure 100, according to an embodiment of the invention;

FIG. 18 and FIG. 19 are cross-sectional views of the semiconductor structure 100, according to an embodiment of the invention;

FIG. 20 and FIG. 21 are cross-sectional views of the semiconductor structure 100, according to an embodiment of the invention;

FIG. 22 and FIG. 23 are cross-sectional views of the semiconductor structure 100, according to an embodiment of the invention; and

FIG. 24 and FIG. 25 are cross-sectional views of the semiconductor structure 100, according to an embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sublithographic” may refer to a dimension or size less than current dimensions achievable by photolithographic processes, and the term “lithographic” may refer to a dimension or size equal to or greater than current dimensions achievable by photolithographic processes. The sublithographic and lithographic dimensions may be determined by a person of ordinary skill in the art at the time the application is filed.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10°deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Although only a limited number of components, devices, or structures are shown and described, embodiments of the present invention shall not be limited by any quantity otherwise illustrated or discussed herein.

The present invention generally relates to semiconductor structures, and more particularly relates to forming a zero-track skip super via.

Forming an SVIA without track skips is advantageous for increasing circuit density but runs the risk of creating a short between the SVIA and a nearby metal line. While a smaller SVIA may be less likely to short with the nearby metal line, the smaller SVIA may also result in a connection with Mx−1 metal lines having a high resistance path and minimal contact area.

SVIAs may connect an Mx−1 metal level with an Mx+1 metal level. Typically, a track skip is included on the Mx metal level because, as noted above, forming a SVIA with no track skips can result in shorts between the SVIA and metal lines of the intermediate Mx level, causing extensive ultra low-k (ULK) dielectric damage. Alternatively, a smaller (e.g., thinner) SVIA can be formed to avoid such shorts with the Mx metal level, however a smaller SVIA results in a high resistance, minimal contact area between the SVIA and metal lines of an Mx−1 layer.

The claimed invention provides a structure and fabrication process that solves the problems of shorting and having a super via with high resistance and minimal contact area described above, and does so without the need for a track skip or requiring a reduction in overall dimensions of the SVIA. More specifically, the claimed invention solves the problems by including a dielectric layer between the super via and the Mx layer. The claimed invention thereby improves the overall electrical performance of the structure and provides a better dielectric isolation between the SVIA and nearby metal lines.

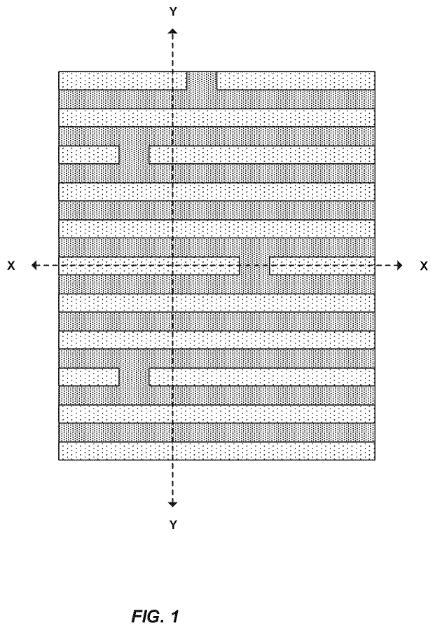

Referring now to FIG. 1, a top view of a generic structure is shown to provide spatial context to the different cross-sectional views and structural orientations of the semiconductor structures shown in the figures and described below.

The generic structure illustrated in FIG. 1 shows a BEOL region of a semiconductor with stacked layers of metal lines crossing perpendicular to one another and connected by vias. FIGS. 1-25 represent cross section views oriented as indicated in FIG. 1

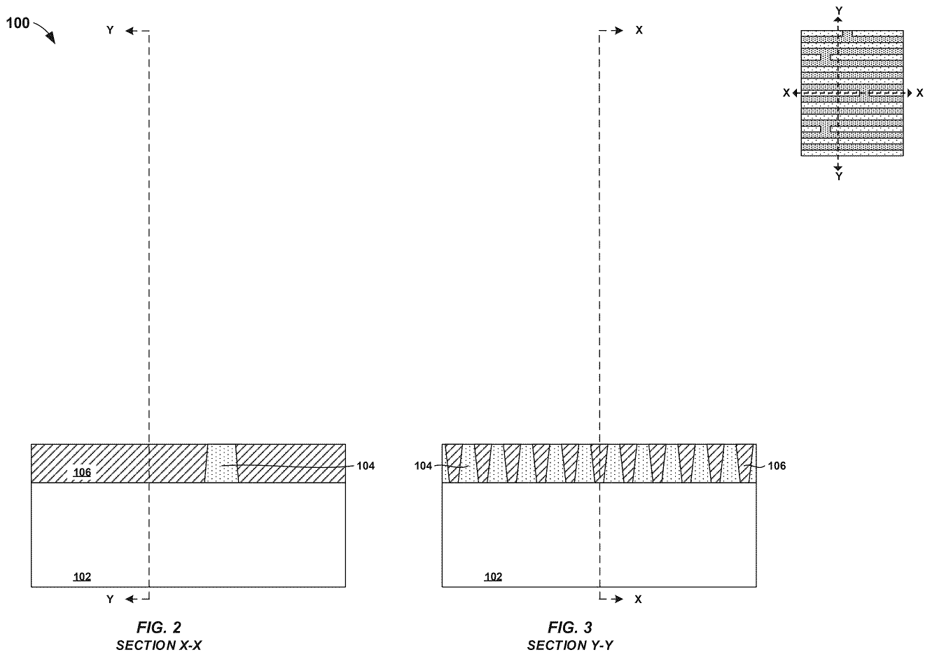

Referring now to FIG. 2 and FIG. 3, a structure 100 is shown during an intermediate step of a method of fabricating a semiconductor structure, according to an embodiment of the invention. FIG. 2 depicts a cross-sectional view of the structure 100 shown in FIG. 3 taken along line X-X and FIG. 3 depicts a cross-sectional view of the structure 100 shown in FIG. 2 taken along line Y-Y.

FIG. 2 and FIG. 3 illustrate the structure 100 following a series of processing steps performed on the structure 100, including Mx−1 formation.

As illustrated, the structure 100 includes a region 102. The region 102 may include front end of line (FEOL) devices, middle of line (MOL) contacts, back end of line (BEOL) interconnects, etc., and may be formed using known techniques.

As further illustrated, an interlayer dielectric (ILD) 104 is formed on top of the region 102. The ILD 104 is composed of any suitable interlayer dielectric material, such as, for example, oxides such as silicon oxide (SiOₓ), nitrides such as silicon nitride (SiₓN_{y}), and/or low-κ materials such as SiCOH or SiBCN. In another embodiment, the ILD 104 is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the ILD 104.

The structure 100 further includes a plurality of metal lines that form a metal layer/level Mx−1, denoted as Mx−1 106, within the ILD 104. The cuts for the Mx−1 106 may be patterned through the ILD 104 down to and exposing the region 102. The patterning may be performed using known techniques. For example, the layer of ILD 104 is patterned through a lithographic patterning and etch process to have a plurality of openings, such as trench openings running from left to right as in FIG. 2 or trench openings running into the paper as in FIG. 3, and the plurality of trench openings are subsequently filled with conductive material to form a plurality of metal lines that comprise the metal layer denoted as Mx−1 106.

Conductive material may be deposited into the cuts for the Mx−1 106 and may cover the top surface of the ILD 104. Then, any excess conductive material on top of the ILD 104 may be removed by a chemical mechanical planarization (CMP) process following the deposition.

The conductive material used to fill the Mx−1 106 may be, for example copper (Cu), aluminum (Al), tungsten (W), ruthenium (Ru), molybdenum niobium, etc., and may further include a metal barrier between the ILD 104 and Mx−1 106 if required to improve adhesion, eliminate material diffusion, and improve electrical performance. Other metal may be used, as well, such as (i) nitrides (e.g., titanium nitride (TiN), hafnium nitride (HfN), hafnium silicon nitride (HfSiN), tantalum nitride (TaN), tantalum silicon nitride (TaSiN), tungsten nitride (WN), molybdenum nitride (MoN), and niobium nitride (NbN)); (ii) carbides (e.g., titanium carbide (TiC), titanium aluminum carbide (TiAlC), tantalum carbide (TaC), and hafnium carbide (HfC)); and (iii) combinations thereof. The deposition techniques include, but not limited to, chemical vapor deposition (CVD), plasma enhanced CVD (PECVD), radio-frequency CVD (RFCVD), physical vapor deposition (PVD), atomic layer deposition (ALD), molecular layer deposition (MLD), molecular beam deposition (MBD), pulsed laser deposition (PLD), liquid source misted chemical deposition (LSMCD), sputtering, and/or plating. The so formed Mx−1 106 is therefore insulated by being embedded in and/or surrounded by the ILD 104.

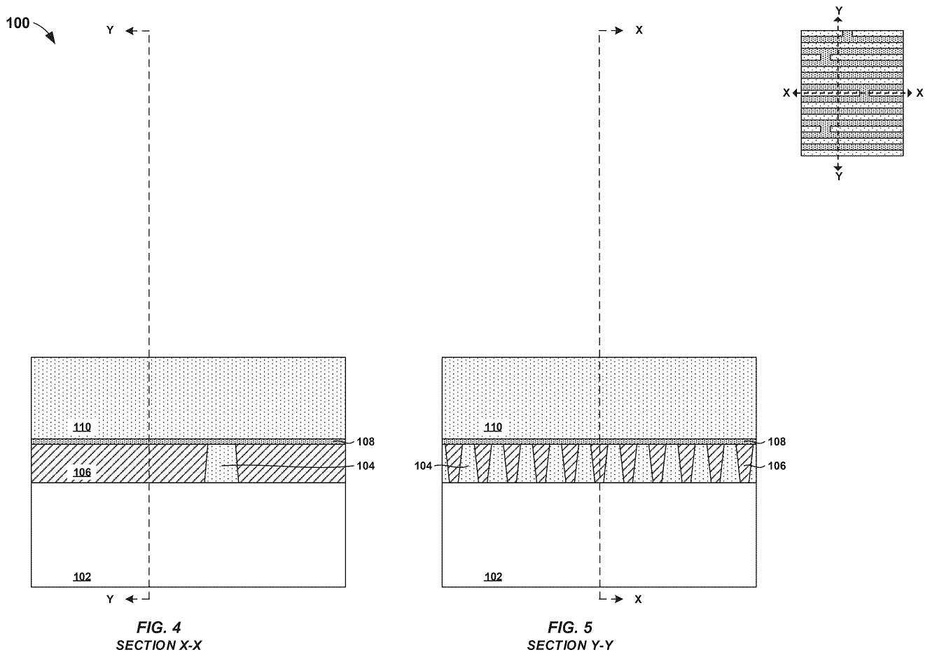

Referring now to FIG. 4 and FIG. 5, the structure 100 is shown during an intermediate step of a method of fabricating a semiconductor structure, according to an embodiment of the invention. FIG. 4 depicts a cross-sectional view of the structure 100 shown in FIG. 5 taken along line X-X and FIG. 5 depicts a cross-sectional view of the structure 100 shown in FIG. 4 taken along line Y-Y.

FIG. 4 and FIG. 5 illustrate the structure 100 following a series of processing steps performed on the structure 100, including the formation of an etch stop layer (ESL) and formation of an ILD.

An ESL 108 is conformally formed on top of the ILD 104 and the Mx−1 106. The ESL 108 may include any material which affects the desired etch selectivity during subsequent processing. For example, the ESL 108 may be a silicon oxide, an aluminum oxide compound such as AlOx, AlOC, and AlON, a silicon nitride (SiN), a silicon carbide (SiC), SiCOH, aSi, SiNCH, conventional buried oxide (BOX) layer, or other material. It will be understood that ESL 108 can be a combination of two or more layers to provide optimum performance during the etch by increasing selectivity mostly.

The structure 100 further includes an ILD 110 formed conformally on top of the ESL 108. As illustrated, the ESL 108 separates the ILD 104 and the Mx−1 106 from the ILD 110. The ILD 110 may be formed of dielectric material using known techniques, for example the materials and techniques described with respect to forming the ILD 104.

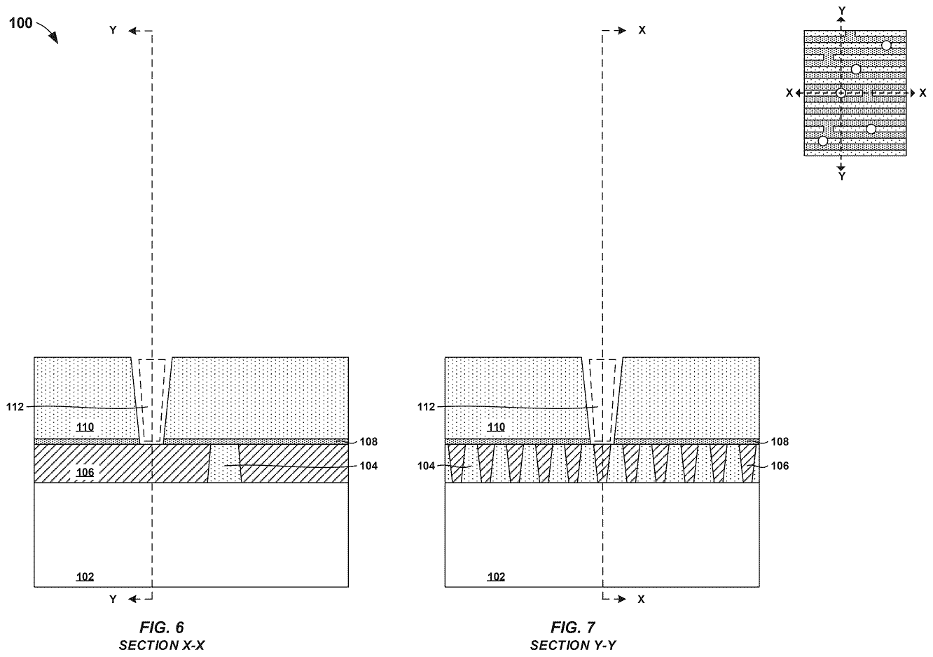

Referring now to FIG. 6 and FIG. 7, the structure 100 is shown during an intermediate step of a method of fabricating a semiconductor structure, according to an embodiment of the invention. FIG. 6 depicts a cross-sectional view of the structure 100 shown in FIG. 7 taken along line X-X and FIG. 7 depicts a cross-sectional view of the structure 100 shown in FIG. 6 taken along line Y-Y.

FIG. 6 and FIG. 7 illustrate the structure 100 following a series of processing steps performed on the structure 100, including forming metal lines for the Mx metal level.

Next, a patterning is performed on the ILD 110. In embodiments, and as illustrated, the patterning may go through the ESL 108, exposing a top surface of at least one metal line of the Mx−1 106. In other embodiments, the patterning is performed up to or only partially through one or more layers of the ESL 108 without exposing a top surface of at least one metal line of the Mx−1 106. In the latter embodiments, the ESL 108 or layers thereof may be subsequently removed, for example during/following removal of a dielectric layer 116 (described in greater detail forthcoming). The Mx cut patterning results in an Mx cut 112 and may be performed according to known techniques, for example those described with respect to the cut patterning used to form the Mx−1 106. The Mx cut 112 may be roughly conical in shape.

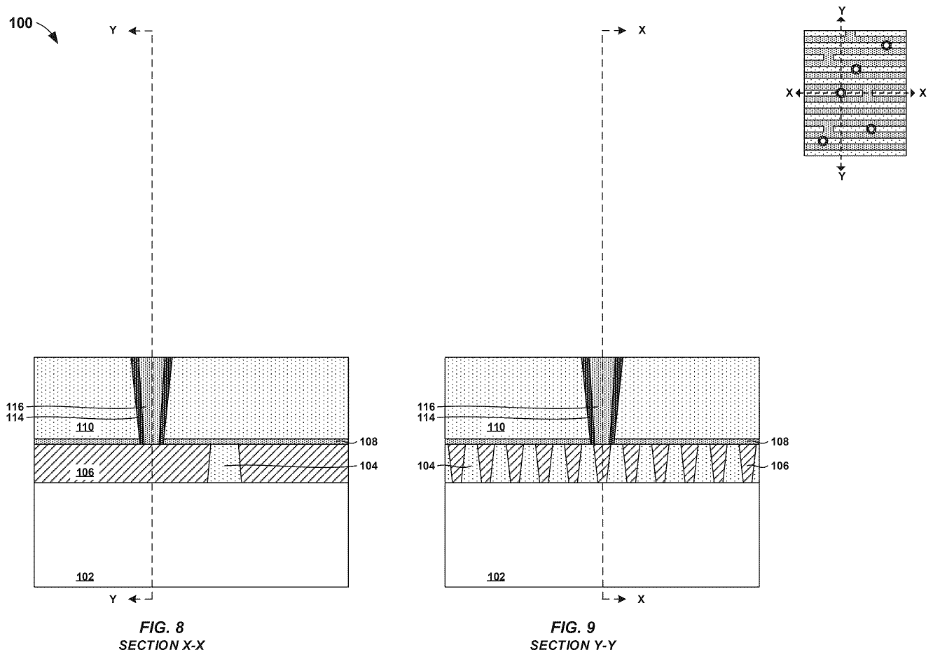

Referring now to FIG. 8 and FIG. 9, the structure 100 is shown during an intermediate step of a method of fabricating a semiconductor structure, according to an embodiment of the invention. FIG. 8 depicts a cross-sectional view of the structure 100 shown in FIG. 9 taken along line X-X and FIG. 9 depicts a cross-sectional view of the structure 100 shown in FIG. 8 taken along line Y-Y.

FIG. 8 and FIG. 9 illustrate the structure 100 following a series of processing steps performed on the structure 100, including consecutive deposition of two different layers of dielectric fill.

Next, two dielectric layers are formed within the Mx cut 112. First, a dielectric layer 114 is deposited conformally along the interior of the Mx cut 112. The dielectric layer 114 may also be referred to as an outer layer spacer. As illustrated, the dielectric layer 114 creates a liner on an inner surface of the Mx cut 112 in a hollow, conical shape having an open top and bottom. Alternatively, using another deposition method, the Mx cut 112 may be filled with the dielectric layer 114 before being opened at the top and/or bottom, thereby exposing a top surface of at least one metal line of the Mx−1 106, for example using a process known as etch space etch back.

Then, following deposition of the dielectric layer 114, a dielectric layer 116 is used to fill remainder of the Mx cut 112, forming a solid, conical shape that contacts a top surface of at least one metal line of the Mx−1 106 and/or the ESL 108 (e.g., when the ESL 108 is not previously etched). The dielectric layer 116 may also be referred to as a dielectric core. As illustrated, the dielectric layer 114 and the dielectric layer 116 both extend down through the ILD 110 and the ESL 108. In other embodiments, however, the dielectric layer 114 and the dielectric layer 116 may extend down to the ESL 108 or a layer thereof without extending completely through the ESL 108. Then, any excess dielectric material may be removed through a CMP process.

In embodiments, the dielectric layer 114 and the dielectric layer 116 are different materials and may be comprised of any suitable interlayer dielectric material, such as, for example, those described with respect to the ILD 104. In some embodiments, the dielectric layer 116 can be composed of a similar material as described with respect to the ESL 108.

In one embodiment, the dielectric layer 116 is conformally deposited using a highly conformal deposition process, such as atomic layer deposition (ALD), to ensure that the recessed area is sufficiently filled with dielectric material. Other deposition methods such as chemical vapor deposition (CVD), physical vapor deposition (PVD) and PVD can be used to deposit a highly conformal layer of dielectric material to fill the recesses area.

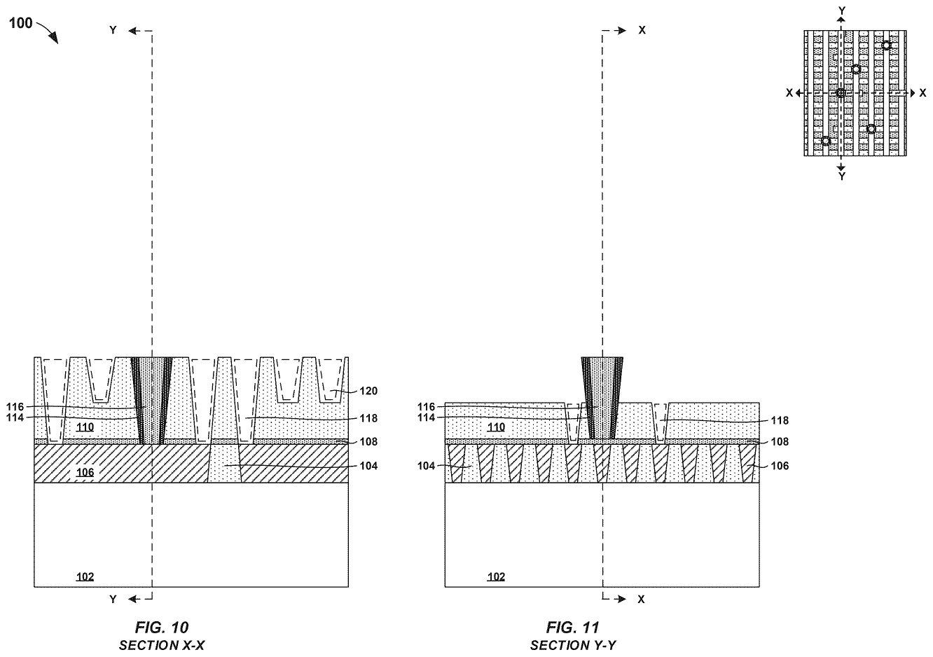

Referring now to FIG. 10 and FIG. 11, the structure 100 is shown during an intermediate step of a method of fabricating a semiconductor structure, according to an embodiment of the invention. FIG. 10 depicts a cross-sectional view of the structure 100 shown in FIG. 11 taken along line X-X and FIG. 11 depicts a cross-sectional view of the structure 100 shown in FIG. 10 taken along line Y-Y.

FIG. 10 and FIG. 11 illustrate the structure 100 following a series of processing steps performed on the structure 100, including Mx and Vx−1 cut patterning.

Next, the ILD 110 is patterned to form one or more Vx−1 cuts 118. As illustrated, the Vx−1 cuts 118 extend down through the ILD 110 and fully opens the ESL 108, exposing a top surface of at least one metal line of the Mx−1 106. The Vx−1 cut patterning may be performed according to known techniques, for example those described with respect to forming the cuts for the Mx−1 106.

As further illustrated, the ILD 110 is patterned to form one or more Mx cuts 120. As illustrated, the Mx cuts 120 extend down into the ILD 110. For example, the Mx cuts 120 may be embedded to roughly two-thirds a depth of the ILD 110. The Mx cuts 120 patterning may be performed according to known techniques, for example those described with respect to forming the cuts for the Mx−1 106.

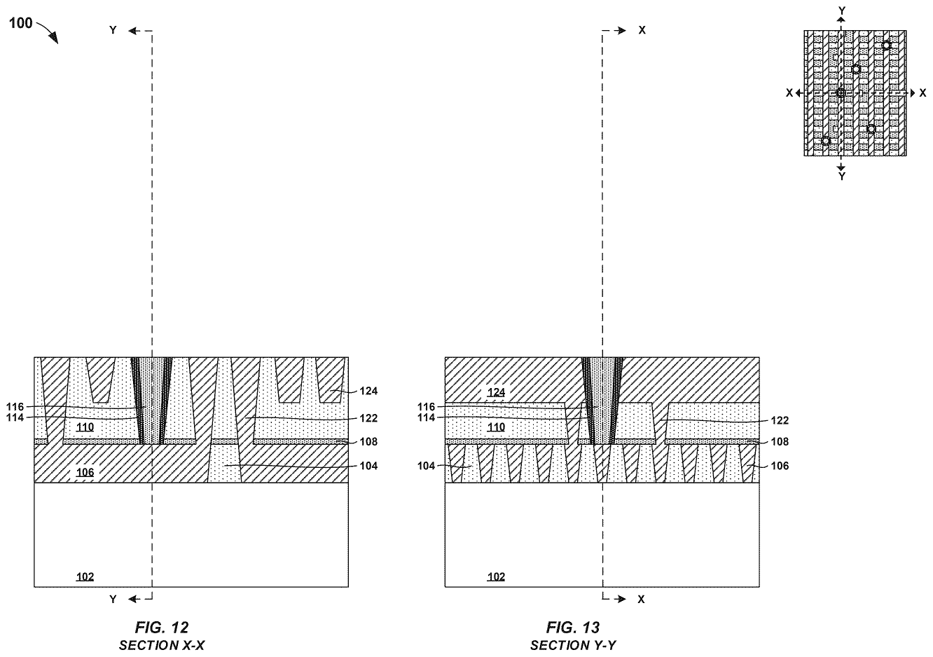

Referring now to FIG. 12 and FIG. 13, the structure 100 is shown during an intermediate step of a method of fabricating a semiconductor structure, according to an embodiment of the invention. FIG. 12 depicts a cross-sectional view of the structure 100 shown in FIG. 13 taken along line X-X and FIG. 13 depicts a cross-sectional view of the structure 100 shown in FIG. 12 taken along line Y-Y.

FIG. 12 and FIG. 13 illustrate the structure 100 following a series of processing steps performed on the structure 100, including Mx and Vx−1 metallization.

Next, the Vx−1 cuts 118 and the Mx cuts 120 are filled with a conductive material, resulting in one or more Vx−1 122 and one or more Mx 124. As illustrated, the Vx−1 122 connects metal lines of the Mx 124 level with metal lines of the Mx−1 106 level. In embodiments, Vx−1 122 and Mx 124 are the same material. Then, any excess conductive material may be removed by a CMP process.

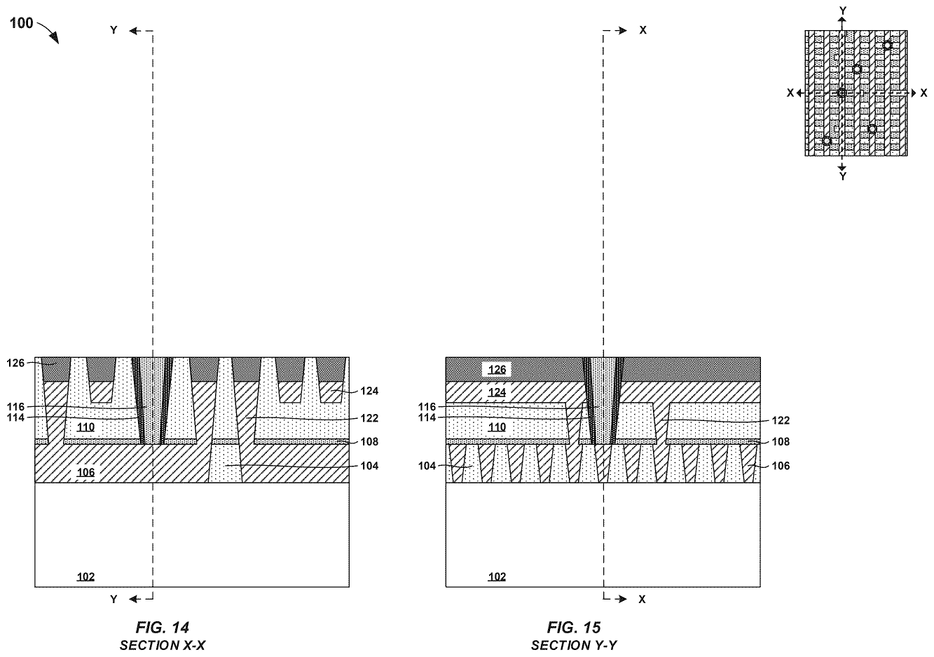

Referring now to FIG. 14 and FIG. 15, the structure 100 is shown during an intermediate step of a method of fabricating a semiconductor structure, according to an embodiment of the invention. FIG. 14 depicts a cross-sectional view of the structure 100 shown in FIG. 15 taken along line X-X and FIG. 15 depicts a cross-sectional view of the structure 100 shown in FIG. 14 taken along line Y-Y.

FIG. 14 and FIG. 15 illustrate the structure 100 following a series of processing steps performed on the structure 100, including recessing the Mx and Vx−1, as well as forming of a dielectric cap.

First, the Vx−1 122 and the Mx 124 may be recessed down, for example using known techniques. As illustrated, a depth to which the Vx−1 122 and the Mx 124 are recessed is uniform. For example, the recess may remove a depth of roughly 10 to 15 nm from a top of the Vx−1 122 and/or the Mx 124.

Next, a dielectric cap 126 is formed within the recessed area of the Vx−1 122 and Mx 124. Here, the dielectric cap 126 insulates the Vx−1 122 and the Mx 124 from subsequent layers of the structure 100. The dielectric cap 126 may be formed by filling the recessed areas of Vx−1 122 and Mx 124 with dielectric materials using known techniques, for example those detailed with respect to the ESL 108.

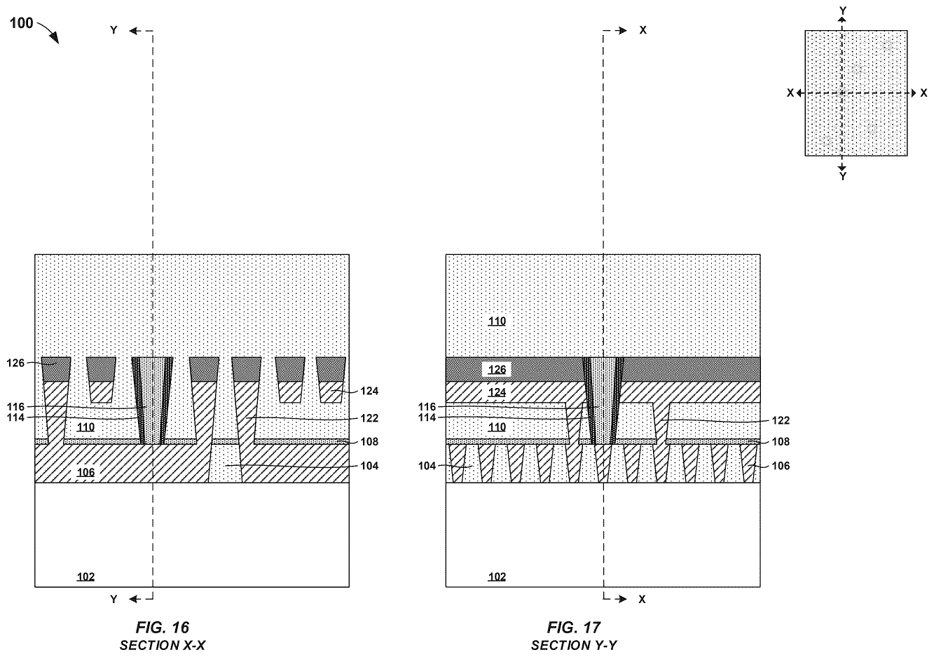

Referring now to FIG. 16 and FIG. 17, the structure 100 is shown during an intermediate step of a method of fabricating a semiconductor structure, according to an embodiment of the invention. FIG. 16 depicts a cross-sectional view of the structure 100 shown in FIG. 17 taken along line X-X and FIG. 17 depicts a cross-sectional view of the structure 100 shown in FIG. 16 taken along line Y-Y.

FIG. 16 and FIG. 17 illustrate the structure 100 following a series of processing steps performed on the structure 100, including ILD deposition.

Next, an additional layer of ILD is formed on top of the dielectric cap 126 and the ILD 110, thereby increasing a thickness of the ILD 110. As illustrated, the additional layer of ILD is conformally deposited on the dielectric cap 126 and the ILD 110. The additional layer of ILD may be comprised of known materials using known techniques, for example those detailed with respect to forming the ILD 104.

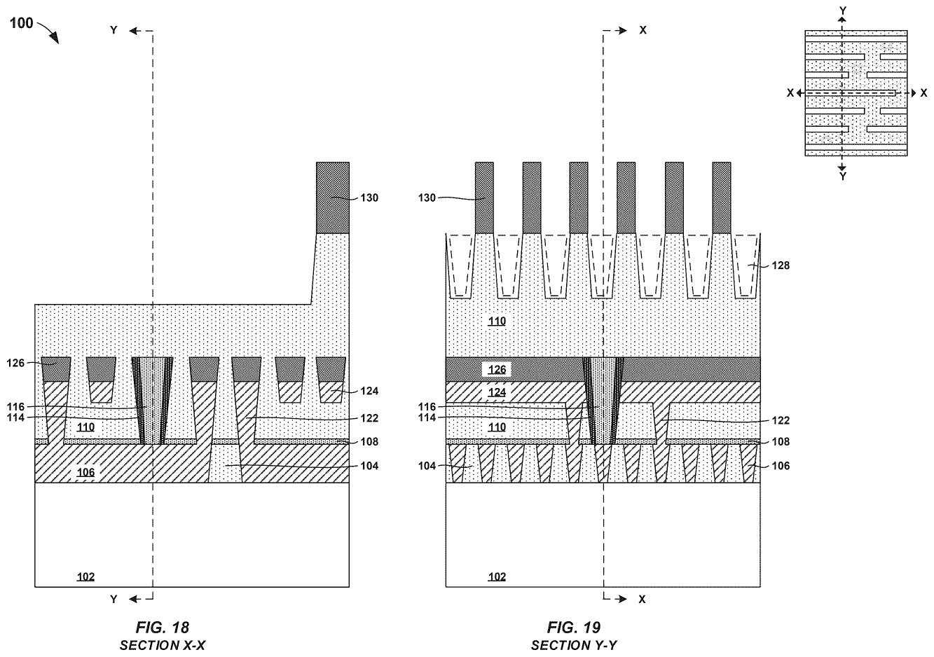

Referring now to FIG. 18 and FIG. 19, the structure 100 is shown during an intermediate step of a method of fabricating a semiconductor structure, according to an embodiment of the invention. FIG. 18 depicts a cross-sectional view of the structure 100 shown in FIG. 19 taken along line X-X and FIG. 19 depicts a cross-sectional view of the structure 100 shown in FIG. 18 taken along line Y-Y.

FIG. 18 and FIG. 19 illustrate the structure 100 following a series of processing steps performed on the structure 100, including patterning a hard mask and an Mx+1 cut.

Next, a hard mask 130 is formed and subsequently patterned to expose certain portions of the structure 100 according to known techniques. The hard mask 130 can be an organic planarization layer (OPL) or a layer of material that is capable of being planarized or etched by known techniques. In an embodiment, for example, the hard mask 130 can be an amorphous carbon layer able to withstand subsequent processing temperatures. In other embodiments, the hard mask 130 may be titanium nitride (TiN) or W-doped carbon (WDC).

After depositing the hard mask 130, an etching technique is applied to pattern or recess the hard mask 130 according to known techniques. The hard mask 130 is patterned consistent with a size and a location of subsequently formed metal lines of an Mx+1 layer and is performed through the ILD 110, forming one or more Mx+1 cuts 128. As illustrated, a center cut of the Mx+1 cuts 128 align substantially with at least one metal line of the Mx−1 106 and the dielectric layer 116.

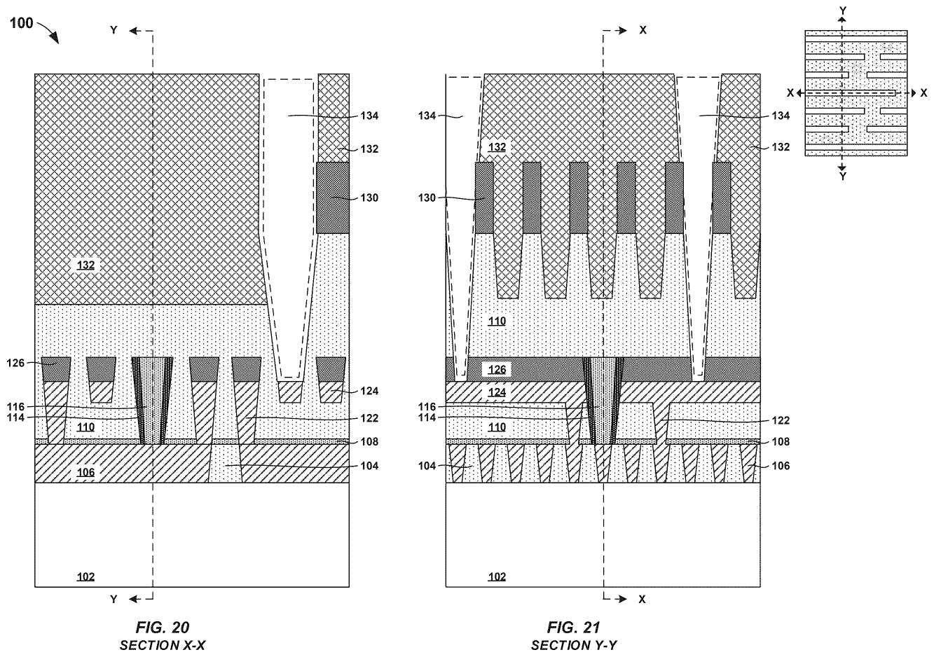

Referring now to FIG. 20 and FIG. 21, the structure 100 is shown during an intermediate step of a method of fabricating a semiconductor structure, according to an embodiment of the invention. FIG. 20 depicts a cross-sectional view of the structure 100 shown in FIG. 21 taken along line X-X and FIG. 21 depicts a cross-sectional view of the structure 100 shown in FIG. 20 taken along line Y-Y.

FIG. 20 and FIG. 21 illustrate the structure 100 following a series of processing steps performed on the structure 100, including fully aligned via patterning.

Following the deposition of an OPL 132 into the Mx+1 cuts 128 and on top of the hard mask 130, one or more fully aligned via cuts 134 are patterned. As illustrated, the fully aligned via cuts 134 extend down through the OPL 132, the ILD 110, and the dielectric cap 126, exposing a top surface of one or more metal lines of the Mx 124. In embodiments, patterning the fully aligned via cuts 134 is performed using known techniques, for example those detailed with respect to forming the cuts for the Mx−1 106. Following the etch sequence described above, the OPL 132 is removed using known techniques.

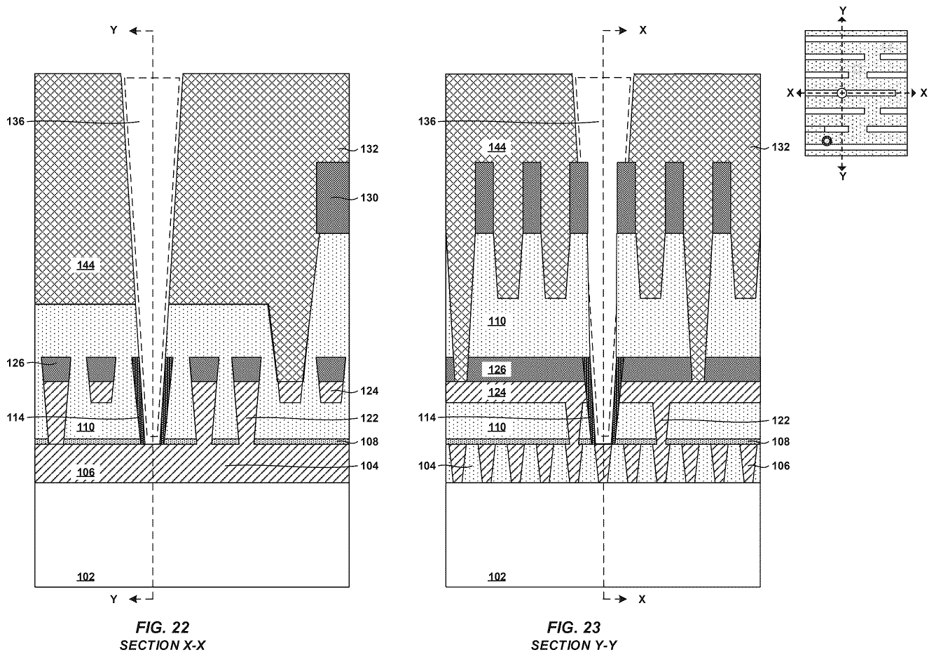

Referring now to FIG. 22 and FIG. 23, the structure 100 is shown during an intermediate step of a method of fabricating a semiconductor structure, according to an embodiment of the invention. FIG. 22 depicts a cross-sectional view of the structure 100 shown in FIG. 23 taken along line X-X and FIG. 23 depicts a cross-sectional view of the structure 100 shown in FIG. 22 taken along line Y-Y.

FIG. 22 and FIG. 23 illustrate the structure 100 following a series of processing steps performed on the structure 100, including fully aligned super-via patterning.

Following deposition of an OPL 144 within the one or more fully aligned via cuts 134, a super via cut 136 is patterned. In embodiments, the super via cut 136 is patterned through the OPL 144, the ILD 110, the dielectric layer 116, and the ESL 108 (if not already removed), exposing a top surface of at least one metal line of the Mx−1 106. Notably, the super via cut 136 extends through and removes the dielectric layer 116 while leaving the dielectric layer 114 intact, leaving the dielectric layer 114 as an outer layer spacer. In embodiments, the super via cut 136 is patterned using known techniques and is fully/substantially aligned with the dielectric layer 114 and at least one metal line of the Mx−1 106. Following the etch sequence described above, the OPL 144 and the hard mask 130 are removed using known techniques.

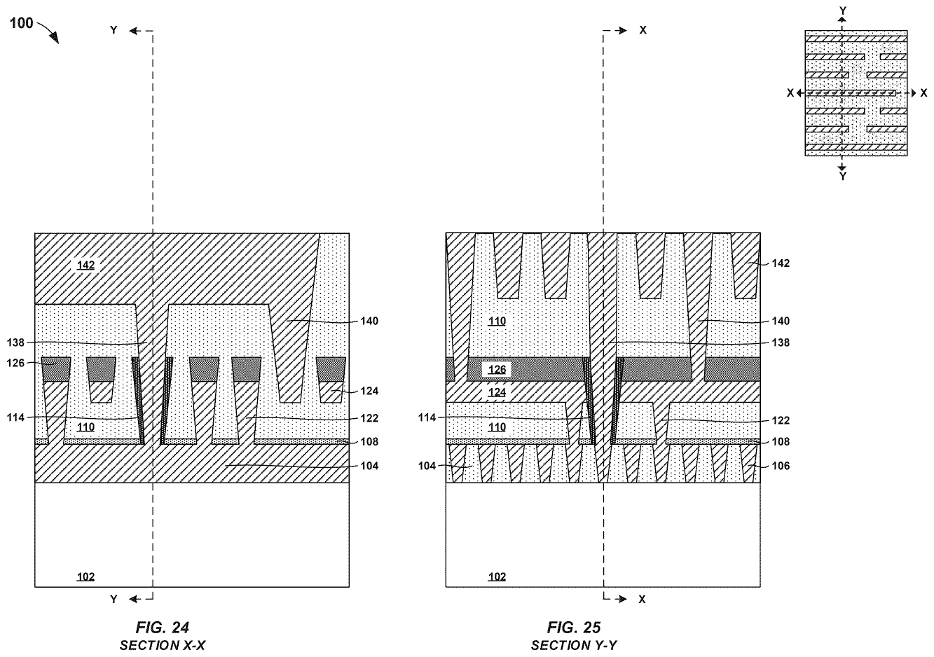

Referring now to FIG. 24 and FIG. 25, the structure 100 is shown during an intermediate step of a method of fabricating a semiconductor structure, according to an embodiment of the invention. FIG. 24 depicts a cross-sectional view of the structure 100 shown in FIG. 25 taken along line X-X and FIG. 25 depicts a cross-sectional view of the structure 100 shown in FIG. 24 taken along line Y-Y.

FIG. 24 and FIG. 25 illustrate the structure 100 following a series of processing steps performed on the structure 100, including Mx+1, Vx, and super via metallization.

Next, the Mx+1 cuts 128, the fully aligned via cuts 134, and the super via cut 136 are filled with a conductive material, resulting in one or more Mx+1 142, one or more Vx 140, and a super via 138. As illustrated, the filling of the one or more Mx+1 142 connect the Mx+1 142 to the one or more Vx 140. Further, the filling of the one or more Vx 140 connect the Vx 140 to the Mx 124. Lastly, the filling of the super via 138 connects at least one metal line of the Mx+1 142 to at least one metal line of the Mx−1 106. The Mx+1 142, the Vx 140, and the super via 138 may be filled with conductive compounds using known techniques, for example those detailed with respect to filling the Mx−1 106.

Importantly, the super via 138 is insulated on all sides from the Mx 124 layer by the dielectric layer 114. As illustrated, the novel layer combinations of the dielectric cap 126 and the dielectric layer 114 prevent connections between the Mx 124 and an out of spec super via 138, and adds extra etch selectivity to during the super via cut 136 formation. In doing so, the claimed invention solves the noted problem of shorting the super via 138 with the Mx 124.

Further, as illustrated, the super via 138 need not be reduced in dimension (e.g., width/diameter/cross-section) to avoid making contact with the Mx 124 metal level. Rather, the super via 138 maintains a nominal size throughout, solving the noted problem of having a high resistance, minimal contact area resulting from the current technique of avoiding shorts by reducing dimensions of the super via 138.

It will be further appreciated that while only one Vx−1 122 via is shown adjacent to the super via 138, in other words connected to directly adjacent metal lines of the Mx−1 106 (i.e., no track skip), in other embodiments, there may be any number of adjacent Vx−1 122 and super vias 138.

Further, although no Vx 140 is shown adjacent to the super via 138 (i.e., Vx 140 and the super via 138 are not connected to directly adjacent metal lines of Mx+1 142), such a configuration is contemplated and made possible by the claimed invention. Here, like in other described embodiments, the dielectric layer 114 insulates the super via 138 from the Mx 124 level.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A structure comprising:
an Mx−1 metal level, an Mx metal level above the Mx−1 metal level, and an Mx+1 metal level above the Mx metal level;
a cut region in the Mx metal level, the cut region having an outer layer spacer; and
a super via connecting the Mx+1 metal level to the Mx−1 metal level through a center of the outer layer spacer.

2. The structure of claim 1, wherein the super via is separated from the Mx metal level by the outer layer spacer.

3. The structure of claim 1, wherein the super via is positioned above a first metal line of the Mx−1 metal level, and wherein a Vx−1 via is positioned above a second metal line of the Mx−1 metal level, and wherein the first metal line and the second metal line are horizontally adjacent metal lines.

4. The structure of claim 3, wherein there is no track skip between the first metal line and the second metal line.

5. The structure of claim 3, wherein the super via is separated from the Vx−1 via by the outer layer spacer.

6. The structure of claim 5, wherein the super via is additionally separated from the Vx−1 via by an interlayer dielectric.

7. The structure of claim 1, wherein a Vx via is fully aligned to at least one metal line of the Mx metal level and at least one metal line of the Mx+1 metal level.

8. The structure of claim 7, wherein the super via has a larger diameter than the Vx via.

9. The structure of claim 1, wherein the super via maintains a substantially similar width between the Mx metal level and the Mx+1 metal level.

10. The structure of claim 1, wherein the outer layer spacer has a hollow, conical shape.

11. The structure of claim 1, wherein metal lines of the Mx metal level are capped by a dielectric cap.

12. The structure of claim 11, wherein the dielectric cap is a same material as the outer layer spacer.

13. A structure comprising:
a super via connecting an Mx−1 metal level to an Mx+1 metal level, wherein the super via is insulated from an intermediate Mx metal level by an outer layer spacer.

14. The structure of claim 13, wherein the Mx+1 metal level is above the Mx metal level, and wherein the Mx metal level is above the Mx−1 metal level.

15. The structure of claim 14, further comprising:
a Vx−1 via connecting the Mx−1 metal level to the Mx metal level, and wherein the super via and the Vx−1 via are connected to adjacent metal lines of the Mx−1 metal level.

16. The structure of claim 13, wherein the outer layer spacer has a hollow, conical shape.

17. The structure of claim 13, further comprising:
a dielectric cap above metal lines of the Mx metal level.

18. The structure of claim 17, wherein a maximum width of the outer layer spacer is equal to a maximum width of the dielectric cap.

19. The structure of claim 17, wherein the outer layer spacer is a same material as the dielectric cap.

20. A method comprising:
forming an Mx−1 metal level within a first interlayer dielectric (ILD);
forming an etch stop layer (ESL) on top of the Mx−1 metal level and the first ILD;
forming a second ILD on top of the ESL;
forming an Mx cut in the second ILD;
filling the Mx cut with a dielectric layer spacer and a dielectric core;
forming an Mx patterning in the second ILD selective to the Mx cut;
filling the Mx patterning to form an Mx metal level;
recessing the Mx metal level;
filling the recesses with a dielectric cap;
forming a third interlayer dielectric;
forming Mx+1 trenches within the third interlayer dielectric;
forming a self-aligned skip via that etches the dielectric core, selective to the dielectric layer spacer; and
forming a full-aligned via by selectively removing the dielectric cap.
